(19) United States
(12) Patent Application Publication
(10) Pub. No.: US 2013/0270689 A1
(43) Pub. Date: Oct. 17, 2013

(54) SEMICONDUCTOR PACKAGE, SEMICONDUCTOR MODULE, AND MOUNTING STRUCTURE THEREOF

(71) Applicants: Kwang Soo KIM, Suwon (KR); Young Ki LEE, Suwon (KR); Bum Seok SUH, Suwon (KR); Kee Ju UM, Suwon (KR); Suk Ho LEE, Suwon (KR); Young Hoon KWAK, Suwon (KR)

(72) Inventors: Kwang Soo KIM, Suwon (KR); Young Ki LEE, Suwon (KR); Bum Seok SUH, Suwon (KR); Kee Ju UM, Suwon (KR); Suk Ho LEE, Suwon (KR); Young Hoon KWAK, Suwon (KR)

(73) Assignee: SAMSUNG ELECTRO-MECHANICS CO., LTD.

(21) Appl. No.: 13/550,067

(22) Filed: Jul. 16, 2012

(30) Foreign Application Priority Data
Apr. 12, 2012 (KR) 10-2012-0037745

(51) Int. Cl. H01L 23/36

(52) U.S. Cl. 257/692; 257/E23.101

(57) ABSTRACT

Provided are a semiconductor package capable of packaging and modularizing power semiconductor devices which are difficult to integrate due to heat generation, a semiconductor package module using the same, and a mounting structure thereof. The semiconductor package includes: a common connection terminal formed to have a flat plate shape; first and second electronic devices respectively bonded to both surfaces of the common connection terminals; first and second connection terminals having a flat plate shape and bonded to the first electronic device; and a third connection terminal having a flat plate shape and bonded to the second electronic device.

### CROSS-REFERENCE TO RELATED APPLICATIONS

This application claims the priority of Korean Patent Application No. 10-2012-0037745 filed on Apr. 12, 2012, in the Korean Intellectual Property Office, the disclosure of which is incorporated herein by reference.

### BACKGROUND OF THE INVENTION

1. Field of the Invention

The present invention relates to a semiconductor package, a semiconductor package module using the same, and a mounting structure thereof, and more particularly, to a semiconductor package allowing for power semiconductor devices, difficult to integrate due to heat generation, to be packaged and modularized, a semiconductor package module using the same, and a mounting structure thereof.

2. Description of the Related Art

Consumer demand for portable electronic devices has rapidly risen in recent times, and in order to meet this demand, electronic components mounted in relevant systems have been required to be smaller and lightweight.

Thus, a method for installing as many devices and wires as possible in a predetermined space, in addition to a method of reducing the size of electronic devices, is a key issue in designing a semiconductor package.

Meanwhile, in the case of power semiconductor devices, a great amount of heat may be generated thereby when driven. Such intense heat affects a lifespan and an operation of electronic goods, so heat dissipation from a package is also an important issue.

To this end, the related art power semiconductor package has a structure in which a power device and a control device are mounted on one surface of a circuit board and a heat dissipation plate for dissipating heat is disposed on the other surface of the circuit board.

However, the related art power semiconductor package has the following defects.

First, as the package is reduced in size, the number of semiconductor devices disposed in the same space is increased, generating a large amount of heat within the package, and here, since the package has a structure in which a heat dissipation plate is only disposed in a lower portion of the package, heat dissipation may not be effectively performed.

Also, in the related art power semiconductor package, when devices are disposed on one surface of a circuit board two-dimensionally, the size of the package is increased.

In addition, in the related art, wiring between devices provided within the semiconductor package or wiring between the devices and an external connection terminal is conducted in a wire bonding manner. Thus, a bonding wire may be deformed or damaged by pressure applied thereto in the process of molding the semiconductor package. Also, a bonded portion between the bonding wire and an device may be delaminated due to heat generated in the driving of the semiconductor package, degrading reliability in the case of using the semiconductor package for a long period of time.

Thus, a semiconductor package having a small size and excellent heat dissipation characteristics is required.

### RELATED ART DOCUMENT

Korean Patent Laid-Open Publication No. 1998-0043254

### SUMMARY OF THE INVENTION

An aspect of the present invention provides a small semiconductor package having excellent heat dissipation characteristics, a semiconductor package module using the same, and a mounting structure thereof.

Another aspect of the present invention provides a semiconductor package without a bonding wire, a semiconductor package module using the same, and a mounting structure thereof.

According to an aspect of the present invention, there is provided a semiconductor package including: a common connection terminal formed to have a flat plate shape; first and second electronic devices respectively bonded to both surfaces of the common connection terminals; first and second connection terminals having a flat plate shape and bonded to the first electronic device; and a third connection terminal having a flat plate shape and bonded to the second electronic device.

The first electronic device may be a power semiconductor device, and the second electronic device may be a diode device.

The common connection terminal may be a collector terminal, the first connection terminal may be a gate terminal, the second connection terminal may be an emitter terminal, and the third connection terminal may be an anode terminal.

The common connection terminal, the first connection terminal, the second connection terminal, and the third connection terminal may be disposed to be parallel to each other.

The common connection terminal, the first connection terminal, the second connection terminal, and the third connection terminal may be disposed to be protruded in the same direction.

The first and second connection terminals and the third connection terminal may have a base substrate for heat dissipation disposed on at least one of outer surfaces thereof.

The base substrate and the connection terminals may have an insulating layer interposed therebetween.

The semiconductor package may further include a molding unit hermetically sealing the first and second electronic devices.

At least one surface of the base substrate may be exposed to the outside of the molding unit.

According to another aspect of the present invention, there is provided a semiconductor package including: first and second electronic devices provided to be stacked on each other; a common connection terminal interposed between the first and second electronic devices and electrically connected to the first and second electronic devices; and a plurality of individual connection terminals bonded to outer surfaces of the first and second electronic devices, wherein the common connection terminal and the plurality of individual connection terminals are formed to have a flat plate shape and are disposed to be parallel to each other.

The common connection terminal and the plurality of individual connection terminals may be disposed to be protruded in the same direction.

At least one outer surface of the individual connection terminals may be provided with a base substrate for heat dissipation disposed thereon.

According to another aspect of the present invention, there is provided a semiconductor package including: first and second electronic devices stacked on each other; and a plurality of external connection terminals bonded between the first and second electronic devices and to outer surfaces of the first and second electronic devices, wherein the external connection terminals may be formed to have a flat plate shape and may be bonded to the first and second electronic device such that at least one surface thereof is in surface-contact with electrodes of the electronic devices.

According to another aspect of the present invention, there is provided a mounting structure of a semiconductor package, including: at least one semiconductor package as described above; and a substrate including first, second and third electrode pads, and a common electrode pad to which the first, second and third connection terminals and the common connection terminal are bonded, and a connection pad electrically connecting the second and third electrode pads, wherein the second and third connection terminals of the semiconductor package are electrically connected by the connection pad of the substrate.

According to another aspect of the present invention, there is provided a semiconductor package module including: at least one semiconductor package as described above; and heat dissipation members disposed on both surfaces of the semiconductor package so as to be in surface-contact with the semiconductor package.

The semiconductor package may include a base substrate for heat dissipation disposed on at least one outer surface of the connection terminals, and the heat dissipation member may be disposed to be in surface-contact with the base substrate.

The heat dissipation member may be a heat sink.

The heat dissipation member may be a water-cooled member including a flow channel formed therein.

### BRIEF DESCRIPTION OF THE DRAWINGS

The above and other aspects, features and other advantages of the present invention will be more clearly understood from the following detailed description taken in conjunction with the accompanying drawings, in which:

FIG. 1A is a perspective view schematically showing a semiconductor package according to an embodiment of the present invention;

FIG. 1B is a projected perspective view of the semiconductor package illustrated in FIG. 1A;

FIG. 2 is a cross-sectional view taken along line A-A′ in FIG. 1;

FIG. 3 is a cross-sectional view taken along line B-B′ in FIG. 1;

FIG. 4 is an exploded perspective view of the semiconductor package of FIG. 1;

FIG. 5 is a perspective view schematically showing a substrate according to an embodiment of the present invention;

FIG. 6 is a perspective view showing a semiconductor package and a substrate according to an embodiment of the present invention;

FIG. 7 is a perspective view showing a state in which the semiconductor package and the substrate in FIG. 6 are coupled; and

FIG. 8 is a perspective view schematically showing a semiconductor package module according to an embodiment of the present invention.

### DETAILED DESCRIPTION OF THE EMBODIMENTS

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe appropriately the method for carrying out the invention. Therefore, the configurations described in the embodiments and drawings of the present invention are embodiments but do not represent the overall technical spirit of the present invention. Thus, the present invention should be construed as including all changes, equivalents, and substitutions included in the spirit and scope of the present invention at the time of filing this application.

Hereinafter, embodiments of the present invention will be described in detail with reference to the accompanying drawings. At this time, it is noted that like reference numerals denote like elements in appreciating the drawings. Moreover, detailed descriptions related to well-known functions or configurations will be ruled out in order not to unnecessarily obscure the subject matter of the present invention. Based on the same reason, it is to be noted that some components shown in the drawings are exaggerated, omitted or schematically illustrated, and the size of each component may not exactly reflect its actual size.

Hereinafter, embodiments of the present invention will be described in detail with reference to the accompanying drawings.

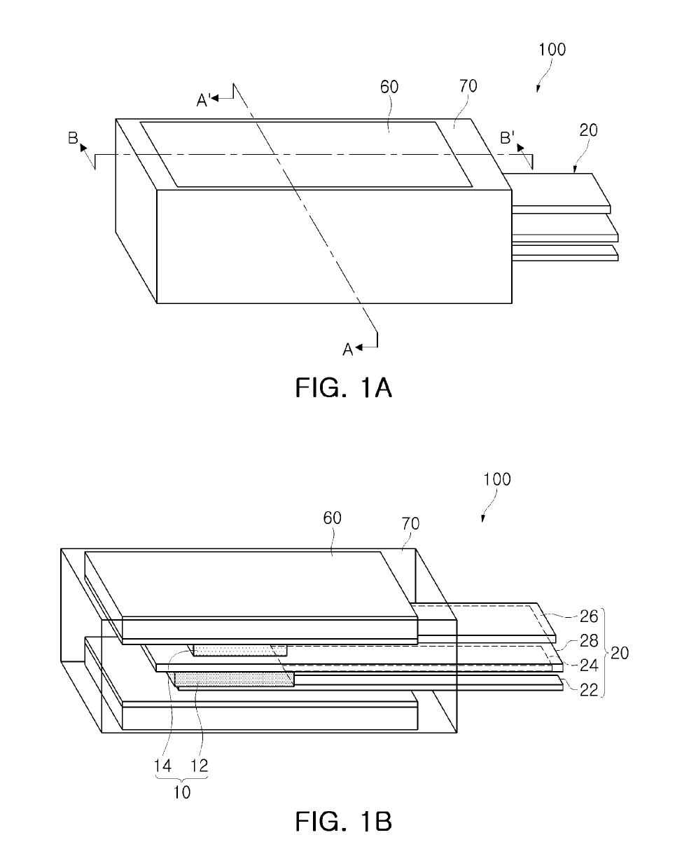

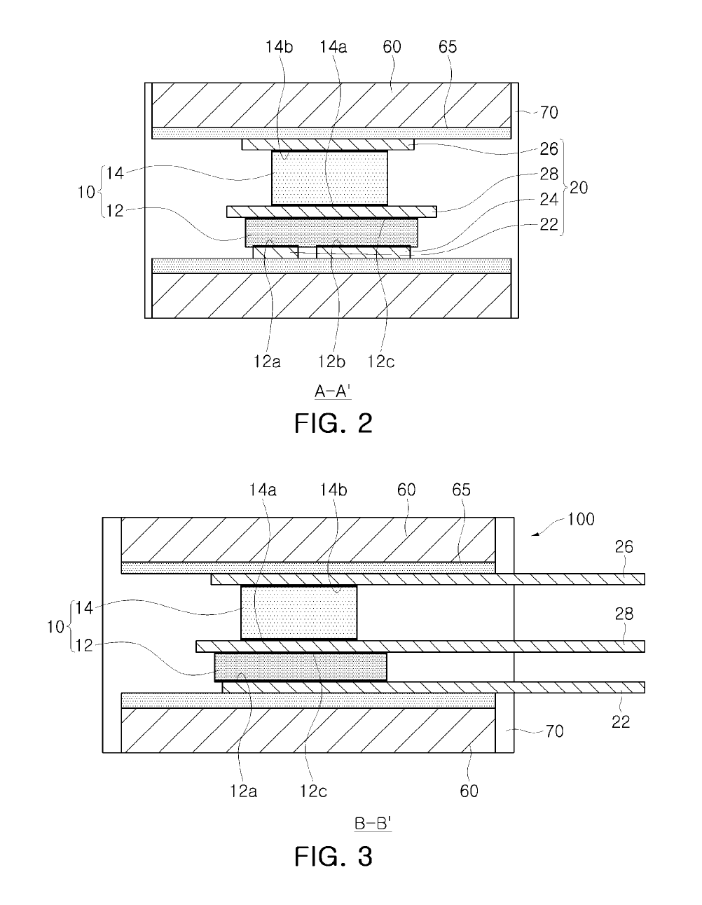

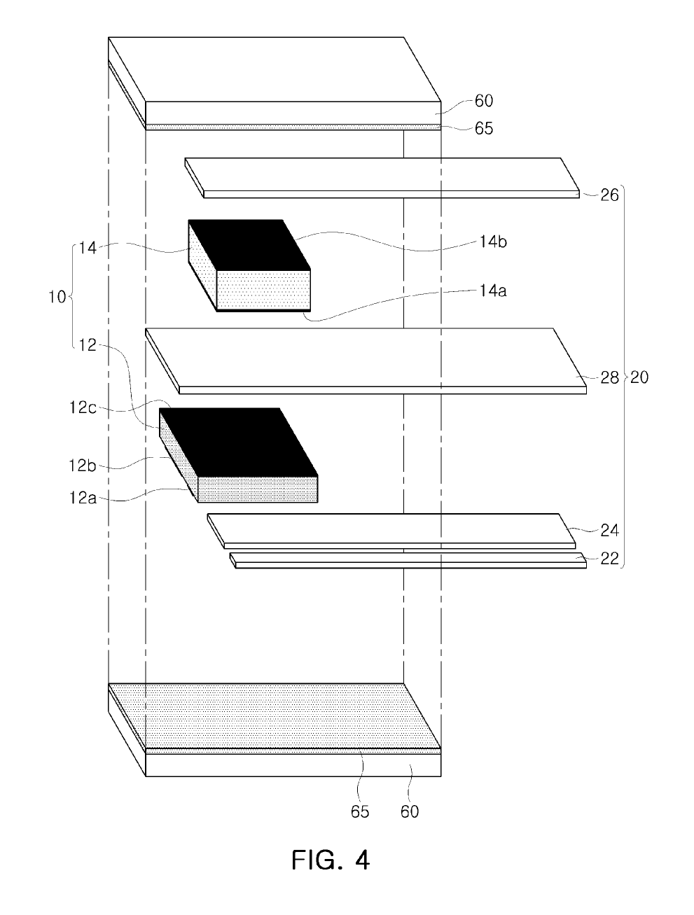

FIG. 1A is a perspective view schematically showing a semiconductor package according to an embodiment of the present invention. FIG. 1B is a projected perspective view of the semiconductor package illustrated in FIG. 1A. FIG. 2 is a cross-sectional view taken along line A-A′ in FIG. 1. FIG. 3 is a cross-sectional view taken along line B-B′ in FIG. 1. FIG. 4 is an exploded perspective view of the semiconductor package of FIG. 1.

With reference to FIGS. 1A through 4, a semiconductor package 100 according to an embodiment of the invention may include an electronic device 10, an external connection terminal 20, a base substrate 60, and a molding unit 70.

The electronic device 10 may include various devices such as a passive device, an active device, and the like. In particular, the electronic device 10 according to the present embodiment may include a first electronic device 12 (e.g., a power semiconductor device) and a second electronic device (e.g., a diode device). Here, the power semiconductor device 12, as the first electronic device 12, may be an insulated gate bipolar transistor (IGBT), and the diode as the second electronic device 14 may be a fast recovery diode (FRD).

Namely, the semiconductor package 100 according to the present embodiment may be a power semiconductor package 100 including the power semiconductor device 12 and the diode device 14 connected between a current input electrode and a current output electrode of the power semiconductor device 12. However, the present invention is not limited thereto.

Also, a plurality of electrodes may be formed on the electronic device 10. In detail, a gate electrode 12a and an emitter electrode 12b may be formed on one surface of the power semiconductor device 12, and a collector electrode 12c may be formed on the other surface of the power semiconductor device 12. Also, a cathode electrode 14a may be formed on one surface of the diode device 14, and an anode electrode 14b may be formed on the other surface of the diode device 14.

In particular, the electronic devices 10 may be disposed to have a mutually laminated form. Namely, in the semiconductor package 100 according to the present embodiment, the electronic devices 10 are not disposed on a plane but are disposed in a laminated manner such that one surface of the diode device 14 faces the other surface of the power semiconductor device 12.

Here, the power semiconductor device 12 and the diode device 14 are bonded to both surfaces of a collector connection terminal 28 as a common connection terminal (to be described later) and laminated.

A plurality of external connection terminals 20 are provided and may be formed of a flat metal plate. Thus, the external connection terminals 20 according to the present embodiment are in surface-contact with the respective electronic devices 10 and are bonded to the electrodes 12a to 12c and 14a to 14b of the respective electronic devices 10.

The external connection terminals 20 according to the present embodiment may include first, second, and third connection terminals 22, 24, and 26, as individual connection terminals, and a common connection terminal 28. Here, the first connection terminal 22 may be a gate connection terminal 22 connected to the gate electrode 12a, the second connection terminal 24 may be an emitter connection terminal 24 connected to the emitter electrode 12b, and a third connection terminal 26 may be an anode connection terminal 26 connected to the anode electrode 14b. Also, the common connection terminal 28 may be a collector connection terminal 28 connected to the collector electrode 12c.

Also, one surface of the collector connection terminal 28 is bonded to the collector electrode 12c of the power semiconductor device 12, and the other surface thereof is bonded to the cathode electrode 14a of the diode device 14. Namely, the collector connection terminal 28 is interposed and bonded between the power semiconductor device 12 and the diode device 14.

Accordingly, the collector electrode 12c of the power semiconductor device 12 and the cathode electrode 14a of the diode device 14 are electrically connected by means of the collector connection terminal 28 and electrically connected to the outside, while sharing the collector connection terminal 28.

A plurality of external connection terminals 20 may be formed to have a flat plate shape and are disposed to be parallel to each other. Also, as illustrated, in the present embodiment, a case in which the common connection terminal 28 and the plurality of individual connection terminals 22, 24, and 26 are disposed to be protruded in the same direction is taken as an example. However, the present invention is not limited thereto. Namely, the external connection terminals 20 may be disposed at certain angles therebetween, disposed to be protruded in different directions, or the like. That is, the external connection terminals 20 may be disposed in various forms as necessary, as long as they are in surface-contact with the electronic devices 10 and bonded to the electronic devices 10.

The external connection terminals 20 may be formed of a material such as copper (Cu), aluminum (Al), or the like, but the present invention is not limited thereto.

The base substrate 60 is disposed on at least any one of positions outside the individual connection terminals 22, 24, and 26 and dissipates heat generated from the electronic devices 10 to the outside.

In order to effectively dissipate heat to the outside, the base substrate 60 may be formed of a metallic material. Here, a relatively inexpensive aluminum (Al) or aluminum alloy while having excellent heat conductivity characteristics may easily be used as a material for forming the base substrate 60. However, the present invention is not limited thereto and any materials, such as graphite, or the like, rather than metal, may be variably used as long as they have excellent heat conductivity characteristics.

Also, in order to prevent the base substrate 60 and the external connection terminals 20 from being electrically connected and shorted, the semiconductor package 100 according to the present embodiment may include an insulating layer 65 interposed between the base substrate 60 and the external connection terminals 20.

The insulating layer 65 may be formed of various materials as long as they have relatively high heat conductivity, bond the external connection terminals 20 to firmly fix them, and electrically insulate them. For example, the insulating layer 65 may be formed of an insulating adhesive such as an epoxy resin, or the like. However, the present invention is not limited thereto.

The molding unit 70 covers to hermetically seal the electronic devices 10 and portions of the external connection terminals 20 bonded to the electronic elements 10 to protect the electronic devices 10 against the outer environment. Also, the molding unit 70 encompasses the electronic elements 10 at an outer side to fix them to thereby stably protect the electronic devices 10 against external impacts.

The molding unit 70 according to the present embodiment is formed such that at least one surface of the base substrate 60 is exposed to the outside. Namely, the molding unit 70 may be formed to cover a portion, rather than the entirety, of the base substrate 60.

Thus, the semiconductor package 100 according to the present embodiment has a substantially rectangular parallelepiped shape due to the molding unit 70, and a heat dissipation substrate 80 may be exposed from at least two sides of the rectangular parallelepiped.

The molding unit 70 may be formed of an insulating material. In particular, a material such as a silicon gel having relatively high thermal conductivity, a thermally conductive epoxy, a polyimide, or the like, may be used to form the molding unit 70.

Hereinafter, a method of fabricating the semiconductor package 100 according to the present embodiment will be described. The fabrication method according to the present embodiment will be described with reference to FIG. 4 based on the direction illustrated in FIG. 4.

In the method of fabricating the semiconductor package 100 according to the present embodiment, first, an operation of disposing the gate connection terminal 22 and the emitter connection terminal 24 is performed.

Here, the gate connection terminal 22 and the emitter connection terminal 24 may be disposed on a separate flat area (e.g., a jig, or the like). Also, the gate connection terminal 22 and the emitter connection terminal 24 may be prepared in a state in which the base substrate 60 is attached to an outer side of the gate connection terminal 22 and the emitter connection terminal 24.

Next, an operation of disposing the power semiconductor device 12 on the gate connection terminal 22 and the emitter connection terminal 24 in a flip chip bonding manner is performed.

Then, an operation of disposing the collector connection terminal 28 on the power semiconductor device 12 is performed.

Thereafter, an operation of disposing the diode device 14 on the collector connection terminal 28 such that the cathode electrode 14a of the diode device 14 faces the collector connection terminal 28.

Subsequently, an operation of disposing the anode connection terminal 26 on an upper portion of the diode device 14 is performed. Here, the anode connection terminal 26 may be disposed in a state in which the base substrate 60 is bonded to an outer side of the anode connection terminal 26. However, when the anode connection terminal 26 is prepared alone, without the base substrate 60, an operation of bonding the base substrate 60 to an outer side of the anode connection terminal (or the gate and emitter connection terminals) may be further performed.

Then, an operation of bonding the electronic devices 10 and the external connection terminals 20 may be performed. Here, the respective electrodes of the electronic devices 10 and the respective external connection terminals 20 may be physically bonded and electrically connected by solder, epoxy having electric conductivity, or the like.

Namely, in the foregoing respective operations, solder or conductive epoxy is interposed or applied between the electrodes of the electronic device 10 and the respective external connection terminals 20, and then, collectively cured in this operation, thus bonding the electronic devices 10 and the external connection terminals 20.

Also, the electronic devices 10 and the external connection terminals 20 may be bonded through a method such as sintering, or the like.

Meanwhile, in the present embodiment, a case in which the bonding operation is finally performed once to collectively bond all the external connection terminals 20 to the electronic devices 10 is taken as an example. However, the present invention is not limited thereto. Namely, the respective external connection terminals 20 may be bonded in each operation when they are disposed on the electronic devices 10, or various configurations may be applied as necessary.

When the electronic devices 10, the external connection terminals 20, and the base substrate 60 are all coupled in this order, an operation of finally forming the molding unit 70 is performed.

The molding unit 70 may be formed by disposing the electronic devices 10 coupled with the external connection terminals 20 and the base substrate 60 within a mold, and then, injecting a molding resin, or the like, into the mold.

Accordingly, the semiconductor package 100 according to the present embodiment is completed.

Meanwhile, in the present embodiment, the case in which the power semiconductor device 12 is first disposed is taken as an example, but the present invention is not limited thereto and the diode device 14 may be first disposed. In this case, an operation of disposing the anode connection terminal 26 may be first performed.

Also, the method of fabricating a semiconductor package according to an embodiment of the present invention may be variably applicable. For example, rather than using the method of sequentially laminating the elements, an operation of bonding the gate connection terminal 22 and the emitter connection terminal 24 to the power semiconductor device 12 and an operation of bonding an anode element to the diode device 14 may be separately performed, and then, these elements may be bonded to both surfaces of the collector connection terminal 28.

The semiconductor package 100 configured as described above according to the present embodiment may be normally operated when the anode electrode 14b of the diode device 14 and the emitter electrode 12b of the power semiconductor device 12 are electrically connected.

To this end, in the related art, in general, an element for electrically connecting the anode electrode 14b and the emitter electrode 12b is added within the semiconductor package.

However, in the semiconductor package 100 according to the present embodiment, the anode electrode 14b and the emitter electrode 12b are connected on the substrate when the semiconductor package 100 is mounted thereon, rather than connecting the anode electrode 14b and the emitter electrode 12b within the semiconductor package 100. Thus, a total of four external connection terminals 20 are externally disposed in the semiconductor package 100 according to the present embodiment.

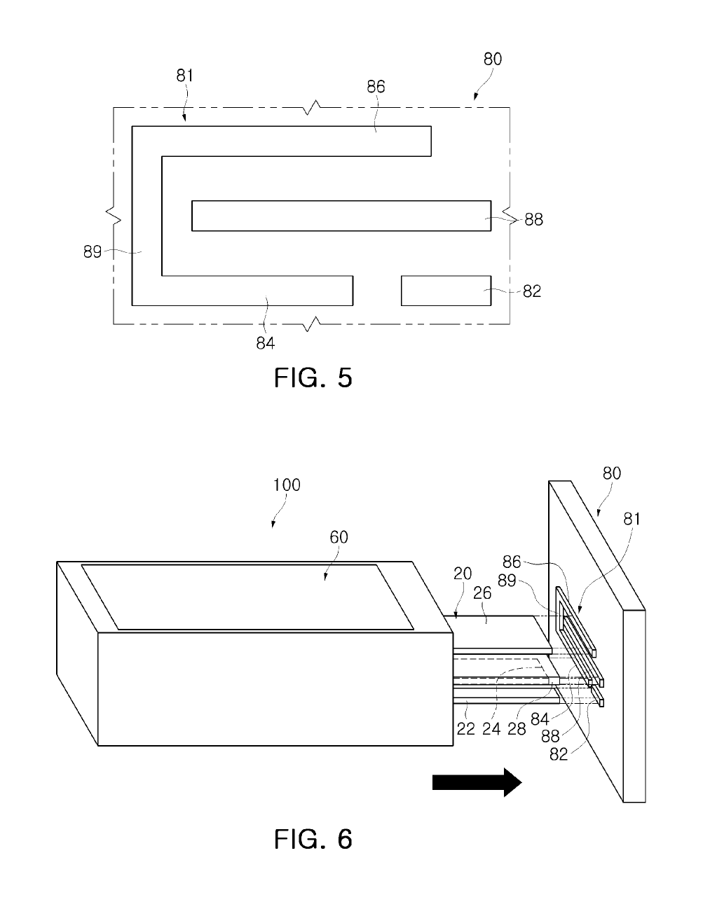

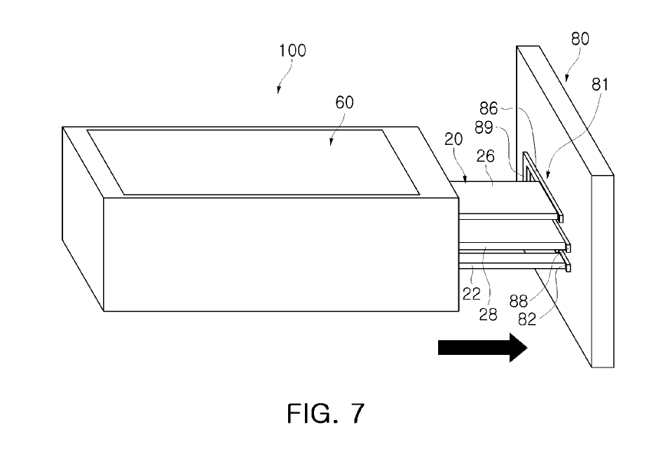

FIG. 5 is a perspective view schematically showing a substrate according to an embodiment of the present invention. FIG. 6 is a perspective view showing a semiconductor package and a substrate according to an embodiment of the present invention. FIG. 7 is a perspective view showing a state in which the semiconductor package and the substrate in FIG. 6 are coupled.

With reference to FIGS. 5 through 7, the substrate 80 on which the semiconductor 100 is to be mounted includes a plurality of electrode pads 81 to which the external connection terminals 20 are to be bonded. In detail, an electrode pad 81 may include first, second, and third electrode pads 82, 84, and 86, and a common electrode pad 88.

In the present embodiment, the first electrode pad 82 may be a gate electrode pad 82 to which the gate connection terminal 22 as the first connection terminal 22 is bonded, and the second electrode pad 84 may be an emitter electrode pad 84 to which the emitter connection terminal 24 as the second connection terminal 24 is bonded, and the third electrode pad 86 may be an anode electrode pad 86 to which the anode connection terminal 26 as the third connection terminal 26 is bonded.

Also, the common electrode pad 88 may be a collector electrode pad 88 to which the collector connection terminal 28 as the common connection terminal 28 is bonded.

Also, the electrode pad 81 according to the present embodiment may include a connection pattern 89 electrically connecting the second electrode pad 84 and the third electrode pad 86, namely, the emitter electrode pad 84 and the anode electrode pad 86.

Accordingly, when the semiconductor package 100 is mounted on the substrate 80, the emitter connection terminal 24 and the anode connection terminal 26 of the semiconductor package 100 are electrically connected by the connection pattern 89 of the substrate 80, thus completing the entire circuits of the semiconductor package 100.

Thus, the semiconductor package 100 according to the present embodiment may be normally operated when mounted on the substrate 80 according to the present embodiment.

In the present embodiment, the case in which the connection pattern 89 is formed on one surface of the substrate 80 is taken as an example, but the present invention is not limited thereto. Namely, various applications may be implemented. For example, a multilayer substrate may be used and a connection pattern may be formed through a wiring pattern formed within the substrate or a connection pattern may be formed through the other surface of the substrate.

Meanwhile, in the present embodiment, the respective external connection terminals 20 are bonded to the electrode pads 81 of the substrate 80 and the semiconductor package 100 is mounted on the substrate 80. In this case, they may be bonded by solder, or the like. However, the present invention is not limited thereto and various applications may be implemented.

For example, a through hole or recess may be formed in each electrode pad 81 of the substrate 80 and an end of the external connection terminal 20 of the semiconductor package 100 may be inserted into the through hole or recess so as to be coupled.

Also, the connection pattern 89 of the substrate 80 may be omitted, and the emitter connection terminal 24 and the anode connection terminal 26 may be electrically connected by using a separate connection member (a conductive wire, a clamp, or the like).

In the semiconductor package 100 according to the present embodiment configured as described above, since the plate type external connection terminal 20 is in surface-contact with the electrode of the electronic device 10 and bonded, rather than using a bonding wire. Thus, in comparison to the related art using a bonding wire, bonding reliability may be obtained, and since a defect such as deformation of the bonding wire in the process of forming the molding unit 70, or the like, may be solved, defect generation may be significantly reduced during the fabrication process.

Also, the semiconductor package 100 according to the present embodiment does not include such an additional element for electrically connecting the emitter connection terminal 24 and the anode connection terminal 26 as in the related art, and may be fabricated through the process of repeatedly laminating (or stacking) the electronic devices 10 and the external connection terminals 20. Thus, the semiconductor package 100 according to the present embodiment may be easily fabricated and a fabrication time and costs thereof may be significantly reduced in comparison to the related art.

In addition, the semiconductor package 100 according to the present embodiment employs a double-sided heat dissipation structure in which the base substrates 60 are disposed on both sides of the laminated electronic devices 10. Also, a heat transmission path is configured between the electronic devices 10 and the base substrates 60 by using a material having relatively high thermal conductivity, and since the base substrate 60 is directly disposed on the external connection terminal 20, a distance between the electronic device 10 and the base substrate 60 may be significantly reduced.

Accordingly, highly enhanced heat dissipation characteristics may be obtained and long-term reliability of the semiconductor package 100 may be secured in comparison to the related art.

In addition, the semiconductor package 100 according to the present embodiment is configured to have a structure in which the electronic devices 10 are sequentially laminated to be disposed, rather than a structure in which the electronic devices 10 are disposed on a single plane. Also, since such a bonding wire, or the like, for electrically connecting the electronic devices 10 and the external connection terminals 20 as in the related art is omitted, the size of the semiconductor package 100 may be reduced.

Thus, the mounting area of the devices may be significantly reduced, and thus, the devices may be easily applied to various types of electronic equipment required to be compact and highly integrated.

Meanwhile, the semiconductor package 100 according to the present embodiment may be used alone or a plurality of semiconductor packages 100 may be coupled to be used as a single module.

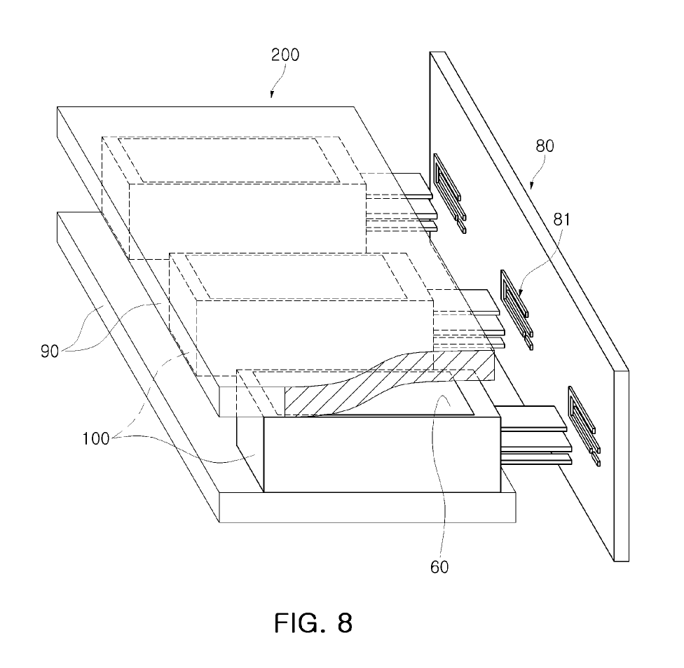

FIG. 8 is a perspective view schematically showing a semiconductor package module according to an embodiment of the present invention, in which the substrate 80 on which a semiconductor package module 200 is mounted is illustrated together.

With reference to FIG. 8, the semiconductor package module 200 according to the present embodiment may include heat dissipation members 90 disposed on both sides of the semiconductor package 100.

The heat dissipation members 90 may be disposed to be in surface-contact with the semiconductor package 100. In particular, according to the present embodiment, two heat dissipation members 90 may be provided to be disposed on both sides of the semiconductor package 100. Thus, one or more semiconductor packages 100 may be disposed between the two heat dissipation members 90.

In particular, the heat dissipation member 90 according to the present embodiment may be disposed to be in contact with the base substrate 60 of the semiconductor package 100. Namely, the exposed base substrate 60 of the semiconductor package 100 and an internal surface of the heat dissipation member 90 may be coupled to be in surface-contact.

Accordingly, heat transmitted from the electronic device 10 to the base substrate 60 may be easily transmitted to the heat dissipation member 90 so as to be discharged to the outside.

The heat dissipation member 90 may be variably formed so long as it can easily discharge heat transmitted from the base substrate 60 or the semiconductor package 100 to the outside.

For example, the heat dissipation member 90 may be a heat sink discharging heat to surrounding air. In this case, an outer surface of the heat dissipation member 90 may include a plurality of projections (e.g., heat dissipation pins), protrusions and depressions, or the like, to enlarge a contact area with air. Also, the heat dissipation member 90 may be a water-cooled member in which a flow channel is formed and a refrigerant flowing through the flow channel absorbs heat. Also, the heat dissipation member 90 may be a heat dissipation system employing a combination of such members.

Meanwhile, in the present embodiment, a plurality of electrode pads 81 including the connection pattern 89 are disposed on positions of the substrate 80 corresponding to the semiconductor package 100. Thus, when the semiconductor package module 200 is mounted on the substrate 80, the plurality of semiconductor packages 100 may be collectively mounted on the substrate 80.

The semiconductor package module 200 according to the present embodiment, configured as described above, has strengths in that heat of the semiconductor package 100 may be effectively discharged through the heat dissipation member 90. Also, since a plurality of semiconductor packages 100 may be modularized to be used, the semiconductor package may be easily fabricated and used.

The semiconductor packages according to these embodiments are not limited to the foregoing embodiments and may be variably applicable. For example, in the foregoing embodiments, the semiconductor package has a rectangular parallelepiped shape overall, but the present invention is not limited thereto. Namely, the semiconductor package may be formed to have a cylindrical shape or a polygonal columnar shape, or may be formed to have various shapes as necessary.

Also, in the foregoing embodiments, the power semiconductor package has been described as an example, but the present invention is not limited thereto and may be variably applicable as long as it is an electronic part in which at least one electronic device is packaged.

As set forth above, according to embodiments of the invention, the semiconductor package does not use a bonding wire and plate type external connection terminals are in surface-contact and bonded with electrodes of the electronic devices. Thus, in comparison to the related art using a bonding wire, bonding reliability may be secured, and since a defect in which the shape of a bonding wire is deformed in the process of forming the molding unit may be solved, the defect generation during the fabrication process may be significantly reduced.

Also, the semiconductor package according to an embodiment of the present invention does not include such an additional element for electrically connecting the emitter terminal and the anode terminal as in the related art, and may be fabricated by simply repeatedly laminating the electronic devices and the external connection terminals. Thus, the semiconductor package may be easily fabricated, and the fabrication time and costs may be significantly reduced in comparison to the related art.

Also, the semiconductor package according to an embodiment of the present invention employs the double-sided heat dissipation structure in which the base substrates are disposed on both surfaces of the laminated devices. Also, a heat transmission path is formed between the electronic devices and the base substrates by using a material having relatively high thermal conductivity. Also, since the base substrates are directly disposed on the external connection terminals, the distance between the electronic devices and the base substrates may be significantly reduced. Also, a plurality of semiconductor packages may be configured as a single module by using a heat dissipation member.

Thus, since relatively more enhanced heat dissipation characteristics may be obtained in comparison to the related art, long-term reliability of the semiconductor package may be secured.

In addition, the semiconductor package according to an embodiment of the present invention may be configured to have a structure in which electronic devices are sequentially laminated to be disposed, rather than a structure in which electronic devices are disposed on a single plane. Also, since such a bonding wire, or the like, for electrically connecting the electronic devices and the external connection terminals as in the related art is omitted, the size of the semiconductor package may be reduced.

Thus, since the mounting area of the devices may be significantly reduced, the semiconductor package may be easily applied to various types of electronic equipment required to be compact and highly integrated.

While the present invention has been shown and described in connection with the embodiments, it will be apparent to those skilled in the art that modifications and variations may be made without departing from the spirit and scope of the invention as defined by the appended claims.

What is claimed is:

1. A semiconductor package comprising:
a common connection terminal formed to have a flat plate shape;
first and second electronic devices respectively bonded to both surfaces of the common connection terminals;
first and second connection terminals having a flat plate shape and bonded to the first electronic device; and
a third connection terminal having a flat plate shape and bonded to the second electronic device.

2. The semiconductor package of claim 1, wherein the first electronic device is a power semiconductor device, and the second electronic device is a diode device.

3. The semiconductor package of claim 2, wherein the common connection terminal is a collector terminal, the first connection terminal is a gate terminal, the second connection terminal is an emitter terminal, and the third connection terminal is an anode terminal.

4. The semiconductor package of claim 1, wherein the common connection terminal, the first connection terminal, the second connection terminal, and the third connection terminal are disposed to be parallel to each other.

5. The semiconductor package of claim 1, wherein the common connection terminal, the first connection terminal, the second connection terminal, and the third connection terminal are disposed to be protruded in the same direction.

6. The semiconductor package of claim 1, wherein the first and second connection terminals and the third connection terminal have a base substrate for heat dissipation disposed on at least one of outer surfaces thereof.

7. The semiconductor package of claim 6, wherein the base substrate and the connection terminals have an insulating layer interposed therebetween.

8. The semiconductor package of claim 6, further comprising a molding unit hermetically sealing the first and second electronic devices.

9. The semiconductor package of claim 8, wherein at least one surface of the base substrate is exposed to the outside of the molding unit.

10. A semiconductor package comprising:
first and second electronic devices stacked on each other;
a common connection terminal interposed between the first and second electronic devices and electrically connected to the first and second electronic devices; and
a plurality of individual connection terminals bonded to outer surfaces of the first and second electronic devices,
the common connection terminal and the plurality of individual connection terminals being formed to have a flat plate shape and disposed to be parallel to each other.

11. The semiconductor package of claim 10, wherein the common connection terminal and the plurality of individual connection terminals are disposed to be protruded in the same direction.

12. The semiconductor package of claim 10, wherein at least one outer surface of the individual connection terminals is provided with abase substrate for heat dissipation disposed thereon.

13. A semiconductor package comprising:
first and second electronic devices stacked on each other; and
a plurality of external connection terminals bonded between the first and second electronic devices and to outer surfaces of the first and second electronic devices,
the external connection terminals being formed to have a flat plate shape and bonded to the first and second electronic device such that at least one surface thereof is in surface-contact with electrodes of the electronic devices.

14. Amounting structure of a semiconductor package, the structure comprising:
at least one semiconductor package of claim 1; and
a substrate including first, second and third electrode pads and a common electrode pad to which the first, second, and third connection terminals and the common connection terminal are bonded, and a connection pad electrically connecting the second and third electrode pads,
the second and third connection terminals of the semiconductor package being electrically connected by the connection pad of the substrate.

15. A semiconductor package module comprising:
at least one semiconductor package of claim 1; and
heat dissipation members disposed on both surfaces of the semiconductor package so as to be in surface-contact with the semiconductor package.

16. The semiconductor package module of claim 15, wherein the semiconductor package includes a base substrate for heat dissipation disposed on at least one outer surface of the connection terminals, and the heat dissipation member is disposed to be in surface-contact with the base substrate.

17. The semiconductor package module of claim 15, wherein the heat dissipation member is a heat sink.

18. The semiconductor package module of claim 15, wherein the heat dissipation member is a water-cooled member including a flow channel formed therein.
